(19) United States
(12) Patent Application Publication
(10) Pub. No.: US 2025/0178155 A1
(43) Pub. Date: Jun. 5, 2025

(54) Chemical Mechanical Polishing Pad

(71) Applicants: DuPont Electronic Materials Holding, Inc., Newark, DE (US); DUPONT SPECIALTY PRODUCTS USA, Wilmington, DE (US); DDP SPECIALTY ELECTRONIC MATERIALS US 8, LLC, Wilmington, DE (US)

(72) Inventors: Philip J. SCOTT, Elkton, MD (US); John R. MCCORMICK, Exton, PA (US); Kenneth LAUGHLIN, Wilmington, DE (US); John C. HOWE, Bear, DE (US)

(21) Appl. No.: 18/952,544

(22) Filed: Nov. 19, 2024

Related U.S. Application Data
(60) Provisional application No. 63/605,238, filed on Dec. 1, 2023.

(51) Int. Cl. B24B 37/24

(52) U.S. Cl. CPC B24B 37/24

(57) ABSTRACT

A chemical mechanical polishing pad comprising a polishing layer that comprises a photocured polymer wherein the photocured polymer is the photoinitiated reaction product of a photocurable material that is free of molecules comprising (meth)acrylate groups and the photocurable material comprises molecules having two or more functional groups wherein the functional groups include a thiol group and ethylenically unsaturated group other than a (meth)acrylate group and the photocure includes reaction of the thiol group with the ethylenically unsaturated group, provided at least some of the molecules comprise three or more functional groups. The chemical mechanical polishing pad can be made by additive manufacturing using stereolithography.

This application claims priority to U.S. Provisional Application No. 63/605,238 filed on Dec. 1, 2023, which is incorporated herein by reference in its entirety.

### FIELD OF THE INVENTION

The invention relates to methods of forming polishing pad for chemical mechanical polishing.

### BACKGROUND OF THE INVENTION

In the fabrication of integrated circuits and other electronic devices, multiple layers of conducting, semiconducting and dielectric materials are deposited onto and removed from a surface of a semiconductor wafer. Thin layers of conducting, semiconducting and dielectric materials may be deposited using a number of deposition techniques. Common deposition techniques in modern wafer processing include physical vapor deposition (PVD), also known as sputtering, chemical vapor deposition (CVD), plasma-enhanced chemical vapor deposition (PECVD) and electrochemical plating, among others. Common removal techniques include wet and dry isotropic and anisotropic etching, among others.

As layers of materials are sequentially deposited and removed, the uppermost surface of the wafer becomes non-planar. Because subsequent semiconductor processing (e.g., metallization) requires the wafer to have a flat surface, the wafer needs to be planarized. Planarization is useful for removing undesired surface topography and surface defects, such as rough surfaces, agglomerated materials, crystal lattice damage, scratches and contaminated layers or materials.

Chemical mechanical planarization, or chemical mechanical polishing (CMP), is a common technique used to planarize or polish work pieces such as semiconductor wafers. In conventional CMP, a wafer carrier, or polishing head, is mounted on a carrier assembly. The polishing head holds the wafer and positions the wafer in contact with a polishing layer of a polishing pad that is mounted on a table or platen within a CMP apparatus. The carrier assembly provides a controllable pressure between the wafer and polishing pad. Simultaneously, a polishing medium (e.g., slurry) is dispensed onto the polishing pad and is drawn into the gap between the wafer and polishing layer. To effect polishing, the polishing pad and wafer typically rotate relative to one another. As the polishing pad rotates beneath the wafer, the wafer sweeps out a typically annular polishing track, or polishing region, wherein the wafer's surface directly confronts the polishing layer. The wafer surface is polished and made planar by chemical and mechanical action of the polishing layer and polishing medium on the surface.

Additive manufacture of a polishing layer having porosity or a three-dimensional pattern on the polishing surface has been proposed. For example, one approach uses a droplet jet 3D printing platform. This requires relatively low viscosity materials that are then photocured. The material applied is then photocured. Examples of photocurable systems suitable for use with such droplet jet 3D printing can include acrylates, methacrylates, or epoxides as reactive groups for photocuring. See e.g., US2019/0224809, US2020/0157265, US2021/0205951, U.S. Pat. No. 11,612,978, and US2019/0337117. These chemistries generally undergo chain-growth photocuring. This can result in materials having limited toughness and elongation properties that can result in undesirably high wear rates.

Another approach uses vat polymerization (including digital light process, scanning laser, or stereolithographic approaches to additive manufacture). See e.g., U.S. Pat. No. 10,350,823. Examples of photocurable systems useful in this method include a composition of acrylate blocked isocyanates and acrylate monomers that can be photopolymerized via acrylate or methacrylate groups. See e.g., US 2022/0119586.

It would be desirable to have chemical mechanical polishing pads that can be produced by additive manufacturing where the pads have good toughness, elongation and wear rate (e.g., toughness, elongation, wear rate are similar to or better than those for commonly used chemical mechanical polishing pads).

It would also be desirable to have an additive manufacturing process for making a polishing layer for a chemical mechanical polishing pad that enables better toughness, better elongation, wear rate, and more flexibility in tuning mechanical properties of the polishing layer. Particularly, it would be desirable to have a chemical mechanical polishing pad manufacturable by additive manufacturing that has good toughness, good elongation, good wear rate.

### SUMMARY OF THE INVENTION

Disclosed herein is a chemical mechanical polishing pad comprising a photocured polymer wherein the photocured polymer is the photoinitiated reaction product of a photocurable material that is free of molecules comprising (meth)acrylate groups and the photocurable material comprises molecules having two or more functional groups wherein the functional groups include a thiol group and ethylenically unsaturated group other than a (meth)acrylate group and the photocure includes reaction of the thiol group with the ethylenically unsaturated group, provided at least some of the molecules comprise three or more functional groups.

Also disclosed is the above polishing pad formed from a method comprising providing a photocurable material in a vessel, selectively curing by irradiation a portion of the photocurable material to form a cured structure, selectively curing by irradiating an additional portion of the photocurable material to further build the cured structure, repeating the selective curing by irradiation until the cured structure has the form of an element of the polishing pad. For example, the element of the polishing pad can be a polishing layer or a subpad layer, or both.

### BRIEF DESCRIPTION OF DRAWINGS

FIG. 1 is a schematic of a bottom-up additive manufacturing apparatus as disclosed herein.

FIG. 2 is a schematic of a top-down additive manufacturing apparatus as disclosed herein.

### DETAILED DESCRIPTION OF THE INVENTION

The chemical mechanical polishing pad disclosed comprises a photocured polymer having good elongation, toughness, and wear rate. The photocure is accomplished by reaction of an ethylenically unsaturated group with a thiol group to form a thioether (or sulfide) link in the polymer. The photocured polymer can form a polishing layer, a subpad layer or both. The polishing layer or subpad layer so formed can be free of abrasive particles. The polishing layer can comprise less than 0.1, less than 0.09, less than 0.08, less than 0.07, less than 0.06, less than 0.05, less than 0.04, less than 0.03, less than 0.02, or less than 0.01 volume percent abrasive particles based on total volume of the polishing layer.

The reaction mixture used to form the photocured polymer is suitable for additive manufacturing, including particularly stereolithography or vat polymerization methods. The reaction mixture is free of molecules comprising (meth)acrylate groups. As used in this specification (meth)acrylate includes acrylates, methacrylates, or mixtures including both acrylates and methacrylates.

The photocured polymer can be formed by reaction of molecules having two or more functional groups where the functional groups are ethylenically unsaturated groups and thiol groups. For example, the molecules have two or more functional groups can include both at least one ethylenically unsaturated group and also at least one thiol group. This molecule can be considered an AB type molecule. As another example the molecules having two or more functional groups include a molecule (A) having two or more ethylenically unsaturated groups and a molecule (B) having two or more thiol groups. An AB type molecule can be used in combination with a molecule (A), in combination with a molecule (B) or in combination with both a molecule (A) and a molecule (B). To provide cross-linking at least a portion of the molecules can have at least three of the reactive groups (i.e., at least three ethylenically unsaturated groups on a molecule, at least three thiol groups, at least two ethylenically unsaturated groups and one thiol group on a molecule or at least two thiol groups and one ethylenically unsaturated group on a molecule). The relative amounts of di-functional (i.e., molecules having two ethylenically unsaturated groups or molecules having two thiol groups) to higher functional (e.g., molecules having more than two ethylenically unsaturated groups or molecules having more than two thiol groups) molecules enables control of cross-link density.

The molecule (A) can comprise an oligomer (also referred to as pre-polymer), a monomer, or a mixture thereof. The molecule (B) can comprise an oligomer (also referred to as pre-polymer), a monomer, or a mixture thereof. By selection of the oligomer and monomer structures and their relative amounts, the properties of the photocured polymer can be tuned. For example, rigid multifunctional alkenes used as molecule (A) can provide improved hardness or toughness. When using an oligomer molecule (A), mixing with a monomer molecule (A) can be useful for viscosity control while avoid using of a solvent that may need to be removed after cure.

A monomeric molecule (A) can be, for example, diallyl phthalate, diallyl isophthalate, diallyl terephthalate, diallyl ether, trimethylolpropane diallyl ether, 1,4-butanediol divinyl ether, di(ethylene glycol) divinyl ether, tri(ethylene glycol) divinyl ether, 1,4-cyclohexanedimethanol divinyl ether, 3,9-divinyl-2,4,8,10-tetraoxaspiro[5.5]undecane, 1,3,5-triallyl-1,3,5-triazine-2,4,6(1H,3H,5H)-trione, 2,4,6-triallyloxy-1,3,5-triazine, 2,2′-diallylbisphenol A, multifunctional acrylamide such as N,N′-methylenebis(acrylamide), or mixtures thereof. These monomeric molecules (A) can be used in a mixture with an oligomeric molecule (A).

Advantageously, a multi-functional isocyanate can be reacted to form a urea-, urethane-, or thiourea-containing molecule A by reacting with a molecule (i.e., an end capping agent) comprising ethylenic unsaturation and at least one nucleophilic functional group (e.g., amine, hydroxy, thiol, or the like). Examples of the capping agent include allyl phenols (e.g., 2-allyl phenol, 4-allyl phenol, eugenol, isoeugenol), alkylene glycol allyl ethers (e.g., ethylene glycol allyl ether), alkylene glycol monovinylethers (e.g., ethylene glycol monovinyl ether, butanediol monovinyl ether) allyl alcohols (e.g., 1-allyl cyclohexanol, allyl alcohol, 3-buten-1-ol, 4-penten-1-ol, 2-methyl-3-buten-1-ol, 5-hexen-1-ol), allyl amines, 1-allyl-2-thiourea, N-allyl-N′-(2-hydroxyethyl)thiourea, hydroxyl norbornene compounds such as 5-norbornene-2-methanol, or a mixture thereof.

The ethylenic unsaturation in molecule (A) or molecule (AB) can comprise for example, a vinyl group, a vinyl ether group, an allyl group, an allyl ether, an allyl ester, a maleimide, a norbornene. Allyls, allyl ethers, and allyl esters can provide a good balance of shelf stability and photo-reactivity. Allyl group as used herein means the group —CH₂—CH═CH₂. Monosubstituted alkenes can provide rapid reaction with the thiol groups while disubstituted alkenes such as crotyl alcohol, trans-3-hexnen-1-ol, will react at a lower rate. The ethylenic unsaturation is preferably not an acrylate group or an acrylic acid group.

For example, to prepare a molecule (A) the following reaction scheme can be used:

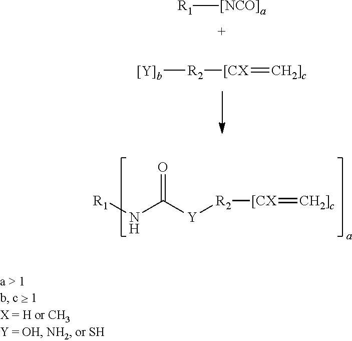

R₁ is a linking group. For example, R₁ can comprise an aliphatic group or an aromatic group or both. For example, R₁ can comprise a divalent alkyl, a cycloalkyl, a divalent aryl, a divalent arylalkyl, or can comprise carbons and a heteroatom such as nitrogen. For example, R₁ can be methylene diphenyl, isophorone, 2,4-toluene, 2,6-toluene, hexamethyl, or uretidione backbones formed from the dimerization of two isocyanate groups. Alternatively, R₁ can be an oligomeric group comprising 2 or more repeat units, 3 or more, up to 150 repeat units. The repeat units can be, for example, alkylene oxides such as ethylene-, propylene-, or tetramethylene oxide, lactones such as caprolactone, saturated and unsaturated forms of hydrocarbon and diene units such as butadiene, isoprene, ethylidene norbornene, dicyclopentadiene, vinyl norbornene, siloxanes such as dimethylsiloxane, and fluorinated units such as vinylidene fluoride and tetrafluoroethylene. R₂ is a linking group. For example, R₂ can comprise an aliphatic group or an aromatic group or both. For example, R₂ can be a divalent alkyl, a divalent aryl, a divalent arylalkyl such as benzyl, phenyl, alkyl, cycloaliphatics such as cyclohexyl. R₂ is provided initially in an end capping agent of the formula [Y]_{b}—R₂—[C═C] . . . . Generally, an end capping agent can include at least one nucleophile (e.g., OH, NH₂, or SH) and an ethylenically unsaturated group.

For example, to form a molecule (A) monomer, a polyisocyanate monomer (e.g., diisocyanate monomer) can be reacted to form a monomer having at least two ethylenically unsaturated groups. Examples of such polyisoscyanate monomers include toluene diisocyanate (TDI) (e.g., 2,4-toluene diisocyanate; 2,6-toluene diisocyanate), diphenylmethane diisocyanate (MDI) (e.g., 4,4′-diphenylmethane diisocyanate); 4,4′-diisocyanato dicyclohexylmethane (H12MDI); naphthalene-1,5-diisocyanate; tolidine diisocyanate; para-phenylene diisocyanate; xylylene diisocyanate; isophorone diisocyanate; hexamethylene diisocyanate; 4,4′-dicyclohexylmethane diisocyanate; cyclohexanediisocyanate; and mixtures thereof.

As another example, the molecule (A) can comprise an oligomer of a urethane or urea-based pre-polymer having two or more ethylenically unsaturated groups; polysiloxane, such as polydimethylsiloxane, having two or more ethylenically unsaturated groups; or a polyalkylene glycol two or more ethylenically unsaturated groups. Where urethane or urea chemistry are desired, such a molecule (A) oligomer can be derived from an isocyanate prepolymer, such as a polyalkylene glycol end-capped with isocyanate groups or a small molecule diisocyanate. Examples of diisocyanates used directly or as prepolymer endcaps include. The isocyanate-terminated urethane prepolymer can have 2 to 30 wt % unreacted isocyanate (NCO) groups. The prepolymer polyol used to form the polyfunctional isocyanate terminated urethane prepolymer can be selected from the group consisting of diols, polyols, polyol diols, copolymers thereof and mixtures thereof. For example, the prepolymer polyol can be selected from the group consisting of polyether polyols (e.g., poly(oxytetramethylene)glycol, poly(oxypropylene)glycol and mixtures thereof); polycarbonate polyols; polyester polyols; polycaprolactone polyols; mixtures thereof; and, mixtures thereof with one or more low molecular weight polyols selected from the group consisting of ethylene glycol; 1,2-propylene glycol; 1,3-propylene glycol; 1,2-butanediol; 1,3-butanediol; 2-methyl-1,3-propanediol; 1,4-butanediol; neopentyl glycol; 1,5-pentanediol; 3-methyl-1,5-pentanediol; 1,6-hexanediol; diethylene glycol; dipropylene glycol; and, tripropylene glycol. For example, the prepolymer polyol can be selected from the group consisting of polytetramethylene ether glycol (PTMEG); ester-based polyols (such as ethylene adipates, butylene adipates); polypropylene ether glycols (PPG); polycaprolactone polyols; copolymers thereof; and mixtures thereof. For example, the prepolymer polyol can be selected from the group consisting of PTMEG and PPG. Examples of commercially available PTMEG based isocyanate terminated urethane prepolymers include Imuthane® prepolymers (available from COIM USA, Inc., such as, PET-80A, PET-85A, PET-90A, PET-93A, PET-95A, PET-60D, PET-70D, PET-75D); Adiprene® prepolymers (available from Lanxess, such as, LF 800A, LF 900A, LF 910A, LF 930A, LF 931A, LF 939A, LF 950A, LF 952A, LF 600D, LF 601D, LF 650D, LF 667, LF 700D, LF750D, LF751D, LF752D, LF753D and L325); Andur® prepolymers (available from Anderson Development Company, such as, 70APLF, 80APLF, 85APLF, 90APLF, 95APLF, 60DPLF, 70APLF, 75APLF. Non-TDI based isocyanate terminated urethane prepolymers can also be used. For example, isocyanate terminated urethane prepolymers include those formed by the reaction of 4,4′-diphenylmethane diisocyanate (MDI) and polyols such as polytetramethylene glycol (PTMEG) or diols such as 1,4-butanediol (BDO), are acceptable. Modified MDI products such as polycarbodiimide-modified MDI (e.g. Isonate 143L) and quasi-prepolymers of MDI reacted with low molecular weight diols (e.g. Isonate 181) such as 1,2-propylene glycol; 1,3-propylene glycol; 1,2-butanediol; 1,3-butanediol; 2-methyl-1,3-propanediol; 1,4-butanediol; neopentyl glycol; 1,5-pentanediol; 3-methyl-1,5-pentanediol; 1,6-hexanediol; diethylene glycol; dipropylene glycol; and tripropylene glycol or combinations thereof can be used. Commercial examples of MDI, polymeric MDI, and MDI prepolymers include ISONATE™ 143L, ISONATE™ 143LP, ISONATE™ 181, ISONATE™ 240, ISONATE™ M 143, ISONATE™ M 320, ISONATE™ M340, ISONATE™ 342, ISOBIND™ 1002, ISOBIND™ 1013, ISOBIND™ 1014, ISOBIND™ 1088, ISOBIND™ 1100, ISOBIND™ 1100 S, ISOBIND™ 1200R, PAPI™ 135, PAPI™ 135C, PAPI™ 17, PAPI™ 20, PAPI™ 27, PAPI™ 580 N, PAPI™ 6146, PAPI™ 901, PAPI™ 94, POLYMERIC MDI 199, POLYMERIC MDI 253, VORANATE™ M 200, VORANATE™ M 220, VORANATE™ 229, VORANATE™ 229 N, VORANATE™ M 230, VORANATE™ M 2940, VORANATE™ M 580, VORANATE™ M 595, VORANATE™ M 600, VORANATE™ M 647, VORANATE™ SD 100, VORANATE™ SD 100 IF from The Dow Chemical Company. Prepolymers can include at least two isocyanate groups. Some commercially available products may include undisclosed mixture of molecules with two isocyanate groups with molecules having more than two isocyanate groups. An example of commercial prepolymer believed to have greater than two isocyanates per molecule is Desmodur N-3400 from Covestro AG.

Examples of molecule (B) include but are not limited to alkyl multifunctional thiols (e.g., 1,2-ethanedithiol, 1,3-propanedithiol, propane-1,2,3-trithiol, 1,4-butanedithiol, 1,5-pentanedithiol, 1,6-hexanedithiol, cyclohexane-1,4-diyldimethanethiol), mercaptopropionate esters (e.g., ethylene glycol bis(3-mercaptopropionate), trimethylolpropane tris(3-mercaptopropionate), pentaerythritol tetrakis(3-mercaptopropionate), tris[2-(3-mercaptopropionyloxy)ethyl]isocyanurate, thioglycolate esters (e.g., 1,4-butanediol bis(thioglycolate)), mercaptoacetate esters (e.g., pentaerythritol tetrakis(mercaptoacetate)), aromatic dithiols, arylalkyl (e.g. aryl with alkylthiol pendant groups) (e.g., 1,3-benzenedimethanethiol, 1,4-benzenedimethanethiol, 4,4′-bis(mercaptomethyl)biphenyl) and thiol-terminated oligomers (e.g., poly(ethylene glycol)dithiol, poly(dimethylsiloxane)dithiol or urethane or urea oligomer).

Examples of AB type molecules include allyl mercaptan and oligomers or prepolymers capped with both an ethylenically unsaturated group and a thiol group. The oligomers capped with both an ethylenically unsaturated group and a thiol group can be prepared as discussed above but providing one capping group comprising ethylenic unsaturation and one capping group with thiol functionality.

The photocured polymer can be formed from a reaction mixture comprising (i) one or more molecule (A) and one or more molecule (B) or (ii) a AB type molecule (optionally also with a molecule (A), a molecule (B), or both). The reaction mixture is free of molecules comprising (meth)acrylate groups.

The reaction mixture preferably includes a photoinitiator. Exposure to activating radiation leads to reaction of the thiol group with the ethylenically unsaturated group. For example, the photoinitiator absorbs activating wavelengths of radiation (e.g., ultraviolet radiation, at wavelength of for example 200-500, 340-390 (e.g., at 385 nanometers (nm)). For example, the photoinitiator, upon radiation, can produce a radical that initiates reaction of the ethylenically unsaturated group with the thiol group to form the photocured polymer. Examples of radical generating photoinitiators include phenyl bis(2,4,6-trimethylbenzoyl)-phosphine oxide (PPO), diphenyl(2,4,6-trimethylbenzoyl)phosphine oxide (TPO), 2,2-dimethoxy-2-phenylacetophenone (DMPA), 2-isopropylthioxanthone (ITX), and benzoyl peroxide. If the ethylenically unsaturated group is highly reactive the free radical may also initiate side reactions of an ethylenically unsaturated group with another ethylenically unsaturated group. As another example, the photoinitiator, upon radiation can produce a base that can deprotonate a thiol group leading to reaction of thiol with the ethylenically unsaturated group. This approach can avoid side reactions of ethylenically unsaturated groups with each other, but it requires that the ethylenically unsaturated group be electron deficient due to adjacent chemical structure on the molecule having the ethylenically unsaturated group. Examples of electron deficient alkenes capable of base-catalyzed coupling reactions with a thiol group include but are not limited to vinyl silanes, maleimides, and acrylamides. Examples of photo base generators include 1,2-dicyclohexyl-4,4,5,5-tetramethylbiguanidium n-butyltriphenylborate (e.g., Fujifilm WPBG-300), (Z)-{[bis(dimethylamino)methylidene]amino}-N-cyclohexyl(cyclohexylamino)methaniminium tetrakis(3-fluorophenyl)borate (e.g., Fujifilm WPBG-345), (e.g., 1,2-diisopropyl-3-[bis(dimethylamino)methylene]guanidium 2-(3-benzoylphenyl)propionate (e.g., Fujifilm WPBG-266), 9-anthrylmethyl N,N-diethylcarbamate (e.g., Fujifilm WPBG-018). In cases where the photobase generator does not absorb at the application wavelength, a photosensitizer can be used, for example thioxanthone species, or other photobase generators that do absorb at the target wavelength. In cases where the photobase generator generates radicals in addition to bases, radical inhibitor species such as 2,2,6,6-tetramethylpiperidine 1-oxyl (TEMPO) can be used to selectively inhibit radical side reactions while allowing base-catalyzed reactions. The amount of photoinitiator in the reaction mixture can be from 0.1, from 0.2, from 0.3, from 0.4 or from 0.5 up to 5, up to 4, up to 3, up 2, or up to 1.5 weight percent based on total weight of the reaction mixture.

The mole ratio of the ethylenically unsaturated groups (e.g., of the molecules (A)) to the thiol groups (e.g., of the molecules (B)) can be from 0.5:1 to 1:0.5, 0.6:1 to 1:0.6, 0.7:1 to 1:0.7. 0.8:1 to 1:0.8, 0.9:1 to 1:0.9, 0.95:1 to 1:0.95, or can be about 1:1.

The reaction mixture can optionally include a UV absorber in addition to the photoinitiator. The UV absorber can facilitate tuning of light penetration (i.e., cure depth) for the reaction mixture. The UV absorber can absorb light, for example, at the wavelength used in the additive manufacture device (e.g., 385 nm). Examples of UV absorbers include 2,2′-dihydroxy-4,4′-dimethoxybenzophenone (DHDMBP) and avobenzone. The amount of UV absorber can be from greater than 0, at least 0.1, at least 0.2, at least 0.3, at least 0.4, or at least 0.5 up to 10, up to 5, or up to 2 wt % based on total weight of the reaction mixture.

The reaction mixture can optionally include a liquid reactive diluent that includes a group (e.g., ethylenic unsaturated group or thiol) that reacts with the other components of the reaction mixture. This liquid reactive diluent can enable viscosity reduction of the reaction mixture to control the viscosity of the reaction mixture. Since the liquid reactive diluent reacts with the other components of the reaction mixture it does not need to be removed after forming the polishing layer. Such removal could cause shrinkage. Examples of liquid reactive diluents include liquid, allyl, allyl ether, vinyl, and vinyl ether compounds such as butanediol monovinyl ether, ethylene glycol vinyl ether, N-vinyl pyrrolidone, vinyl acetate, 1-vinylimidazole, 2-vinyl pyrazine, vinyl pivalate, vinyl propionate, vinyl stearate, vinyl decanoate, ethyl vinyl ether, propyl vinyl ether, butyl vinyl ether, allyl ether, allyl hexanoate, allyl acetate, allyl butyl ether, pentaerythritol allyl ether, allyl methyl carbonate, allyl phenyl ether, allyl heptanoate, allyl butyrate, allyl methyl sulfone, allyl sulfide,. Examples can also include liquid thiol compounds such as mercaptopropionic acid, monofunctional mercaptopropionate esters. The liquid reactive diluent can be present in amounts of 0 to 50%, or 1 to 40%, or 2 to 30%, or 3 to 20%, or 4 to 15% or 5 to 10% based on total weight of the reaction mixture.

The reaction mixture may also include unreactive diluents (e.g., solvents such as dimethyl sulfoxide (DMSO), dimethylformamide (DMF), N-methyl pyrrolidone (NMP), acetone, etc. to lower viscosity. However, this can add the step of solvent removal to the process of forming the polishing layer.

The reaction mixture can also include non-reactive components that are desired to be included in the polishing layer. The components can add functionality such as mechanical reinforcement, or porosity. Examples of these include polymeric beads or particles include expandable polymeric microspheres and the like.

One example of a reaction scheme to form a composition useful in a polishing pad (e.g., as a polishing layer) is as follows. This reaction scheme shows the predominant reaction when an ethylenically unsaturated group that is not strongly electron deficient (e.g., allyls, vinyls, vinyl ethers) react using a photoinitiator that generates a free radical

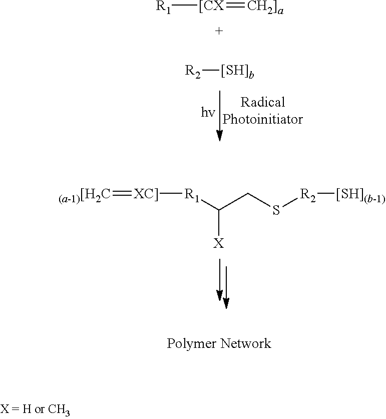

wherein a and b are integers of 2, 3, 4, 5, or 6, provided to get crosslinking at least some of a and b must be 3,4,5, or 6, R₁ is a multivalent linking group consistent with the description of molecules (A), and R₂ is a multivalent linking group consistent with the description of molecules (B).

However, where the ethylenically unsaturated group is electron deficient (e.g., a maleimide or acrylamide) the reaction may include a competing homopolymerization of the ethylenically unsaturated monomer as follows:

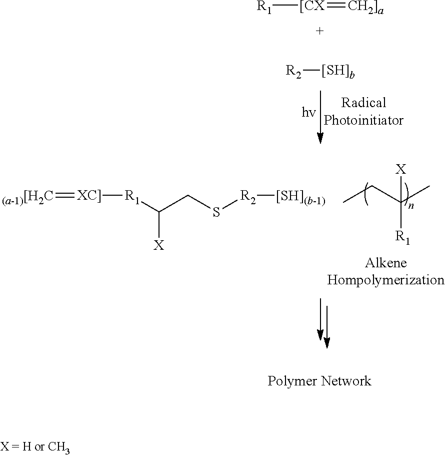

wherein a and b are integers of 2, 3, 4, 5, or 6 provided to get crosslinking at least some of a and b must be 3, 4, 5, or 6, R₁ is a multivalent linking group consistent with the description of molecules (A), and R₂ is a multivalent linking group consistent with the description of molecules (B).

Where a photobase generator is used, the following is a representative reaction scheme:

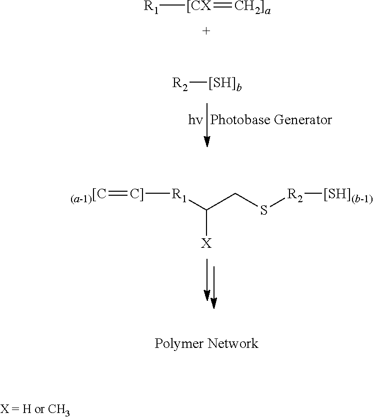

wherein a and b are integers of 2, 3, 4, 5, or 6 provided to get crosslinking at least some of a and b must be 3, 4, 5, or 6, R₁ is a multivalent linking group consistent with the description of molecules (A), and R₂ is a multivalent linking group consistent with the description of molecules (B).

An example of a specific reaction scheme is:

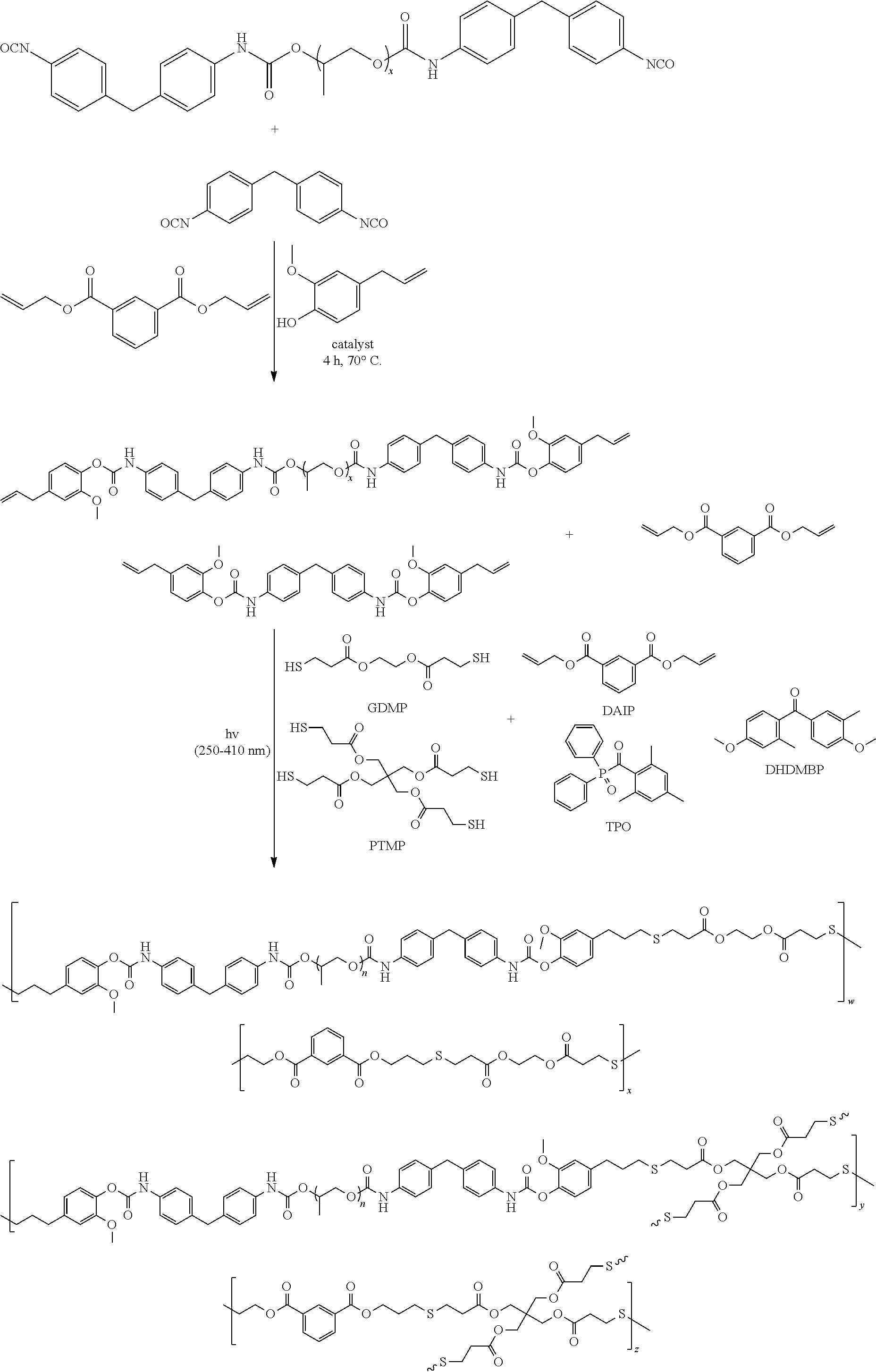

The cured polymers as described herein that can be used as polishing layers in a polishing pad can have a glass transition temperature (T_{g}) according to ASTM D5279-21 and selecting the temperature at maximum tan delta of, for example, from −20° C., or from −10 up to 120, up to 100, up to 70, up to 60, or up to 50° C. The cured polymers as described herein that can be used as polishing layers in a polishing pad can have a tensile modulus according to ASTM D412-05 of, for example, from 1, from 5 or from 10 up to 700, up to 500, or up to 400 megapascals (MPa). The cured polymers as described herein that can be used as polishing layers in a polishing pad can have an elongation according to ASTM D412 of, for example, from 20, from 50, from 70 or from 100 up to 500, up to 450, up to 400, or up to 300%. The cured polymers as described herein that can be used as polishing layers in a polishing pad can have a toughness according to ASTM D412 of, for example from 1, from 2, or from 5 up to 30, or up to 20 MPa. The cured polymers as described herein that can be used as polishing layers in a polishing pad can have a cut rate as described herein of, for example, from greater than 0 up to 2, up to 1.5, up to 1 millimeters per hour (mm/h).

A method of making a chemical mechanical polishing pad as disclosed herein is also provided. The method comprises comprising providing a photocurable material in a vessel, selectively curing by irradiation with activating wavelengths of radiation a portion the photocurable material to form a cured structure, selectively curing by irradiation an additional portion of the photocurable material to further build the cured structure, repeating the selective curing by irradiation until the cured structure has the form of an element of the polishing pad, wherein the photocurable material comprises molecules having two or more functional groups wherein the functional groups are ethylenically unsaturated groups and thiol groups, provided the photocurable material does not include (meth)acrylate groups and at least some of the molecules comprise three or more functional groups where the irradiation leads to reaction of the ethylenically unsaturated group with the thiol group. The photocurable material in the vessel can be a liquid. The photocurable material in the vessel can be flowable under printing conditions. The photocurable material in the vessel can be spreadable.

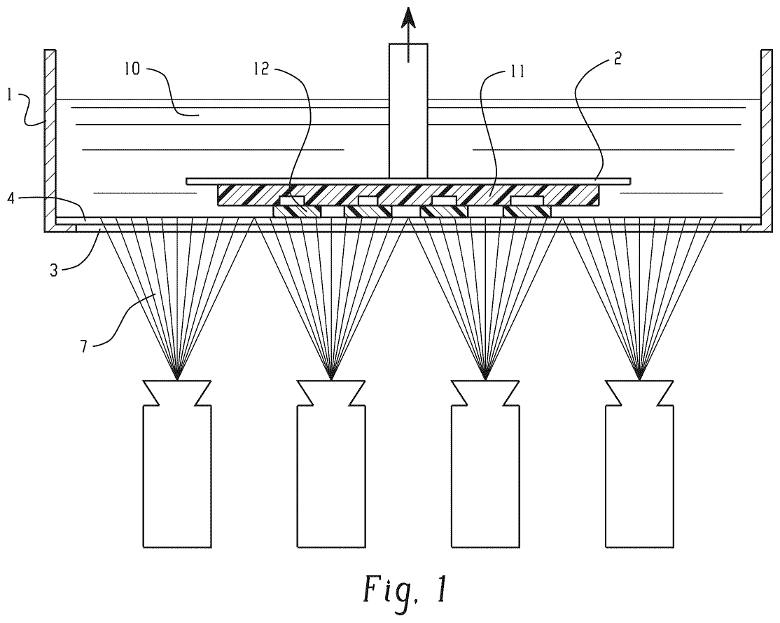

Thus, in one example, as shown in FIG. 1, a bottom-up additive manufacturing apparatus includes vessel 1. Vessel 1 has a portion 3 that is transparent to activation radiation 7. The portion 3 can be at the bottom of the vessel 1. The vessel 1 contains a reaction mixture 10 as described herein (i.e., the reaction mixture comprises a mixture of molecules having two or more functional groups wherein the functional groups are ethylenically unsaturated groups and thiol groups, and the reaction is the reaction of the ethylenically unsaturated group and the thiol group. This reaction mixture can be initiated by exposure to radiation. The reaction mixture can include a photoinitiator that generates a free radical upon exposure to activating wavelengths of radiation). The activation radiation 7 is passed up through the portion 3 of the vessel 1, in an image-wise manner to photocure a portion of the reaction mixture 10 at or immediately above the bottom of the vessel 1. Optionally, a layer 4 may be provided above the surface 3. The layer 4 can prevent sticking of the photocured polymer to the portion 3. The layer 4 can be for example a liquid immiscible with the reaction mixture or a low surface energy coating. The layer 4 is also transparent to the activation radiation 7. A first layer 11 of photocured polymer is formed under a build platform 2. The build platform 2 and first layer 11 are raised allowing the reaction mixture 10 to flow under the first layer 11. Radiation is again passed through the surface 3 in an image-wise manner to form a second layer 12 of the photocured polymer. This is repeated to form additional layers until the desired element of the polishing pad (e.g., the polishing layer) is fully formed.

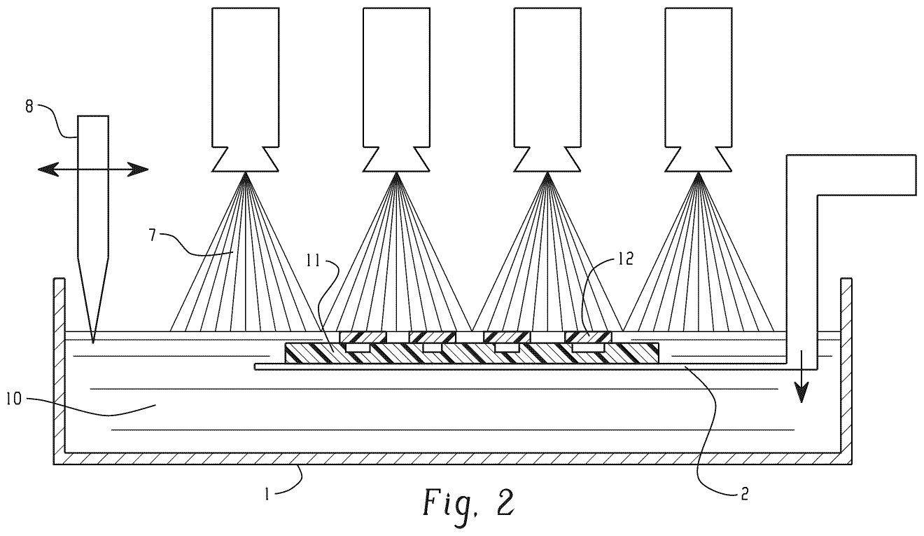

In another example as shown in FIG. 2 a top-down additive manufacturing apparatus includes vessel 1. Vessel 1 contains the reaction mixture 10 as described herein. A layer of the reaction mixture 10 is provided above the build platform 2 and image-wise exposed to radiation 7 to form a first layer 11 of the photocured polymer on the build platform 2. The build platform 2 is then lowered allowing an additional layer of the reaction mixture 10 to cover the first layer 11. A recoating blade 8 can be used to ensure the reaction mixture 10 fully covers the first layer 11. This is particularly helpful for viscous reaction mixtures. The reaction mixture is then again image-wise exposed to radiation 7 to form a second layer 12 of the photocured polymer on the first layer 11. This is repeated to form additional layers until the desired element of the polishing pad (e.g., a polishing layer) is fully formed.

The viscosity of the reaction mixture at printing conditions can be from 0.01 Pascal-seconds (Pa-s) up to 20 Pa-s, or up to 10 Pa-s. Printing conditions can be at room temperature up to 200, up to 150, up to 100, up to 80, up to 50° C. but should be lower than the boiling points and thermal degradation points of the components of the reaction mixture. Room temperature printing conditions can be favored for energy efficiency. The reaction mixture can be in liquid form.

The method as disclosed herein can be used to provide a polishing surface with macro-texture (e.g., grooves, ridges, protrusions, depressions), microtexture (e.g., pores, lattice structures, network structures), or both. For example, grooves can be formed as long or continuous radial, concentric depressions from the polishing surface. The grooves can have depths, for example, of from 0.1, from 0.2, or from 0.3 mm up to 1.5, up to 1.2 or up to 1 mm. The grooves can have widths, for example, of from 0.05, from 0.1, from 0.2, or from 0.3 up to 1, up to 0.8 or up to 0.6 mm. The protrusions protrude above a based top surface of the polishing pad. The can be solid or open cylindrical, cubic, pyramidal or of an irregular cross section (e.g., lobed). The protrusions can have a height of from 0.05 or from 0.1 up to 2, or up to 1.5 mm. The protrusions can include openings in side walls. The protrusions can include a polishing surface raised above the top portion of the polishing layer on supports with a gap between the polishing surface and the top of the base of the polishing pad.

The chemical mechanical polishing pad as disclosed herein can include a subpad that is located opposite a polishing surface of the polishing layer. The polishing layer can be adhered to the subpad after the manufacturing of the subpad using an adhesive material. Alternatively, the entire pad can be formed by additive printing adjusting the composition of photosensitive reaction mixture used to form the subpad to provide the desired properties. The subpad material can be more compliant than the polishing layer. The subpad can comprise a porous layer. Alternatively, the subpad is an open network of interconnected polymer structures.

Examples of polymeric materials for the subpad layer(s) include polyurethanes, polycarbonates, polysulfones, nylons, epoxy resins, polyethers, polyesters, polystyrenes, acrylic polymers, polymethyl methacrylates, polyvinylchlorides, polyvinyl fluorides, polyethylenes, polypropylenes, polybutadienes, polyethylene imines, polyether sulfones, polyamides, polyether imides, polyketones, silicones, copolymers thereof (such as, polyether-polyester copolymers), and combinations or blends thereof. The subpad can be formed using thiol-ene curing from a reaction mixture as described herein that is selected to provide more compliance than is found in the polishing layer. The subpad can be formed from a reaction mixture having polymer precursors (monomers, oligomers, or mixtures thereof) with ethylenic unsaturated groups and thiol groups as described herein. However, the polymer precursors for the subpad selected to provide more compliance than is found in the polishing layer. If the subpad is formed by additive manufacture, the subpad and the polishing layer can be formed sequentially in the reaction vessel 1 with the reaction mixture being changed when moving from one layer to the other. For example, the polishing layer can be formed as described above. When the polishing layer is formed, the reaction mixture 10 can be removed from the vessel 1 and a new reaction mixture added. The same process of exposure to form additional layers on the polishing layer can occur. Alternatively, the subpad could first be formed and then the polishing layer formed by additive manufacture on the subpad as a substrate. For example, the subpad could be formed by additive manufacture, and then the process of forming the polishing layer on the subpad that is on the build platform occurs. As another example, a subpad that is preformed could be provided on the build platform, and the polishing layer formed on the subpad by additive manufacture as described herein.

The chemical mechanical polishing pad can include a window in the polishing layer. The window is formed of a material that is transparent to a wavelength used in end-point detection during the use of the polishing pad. The chemical mechanical polishing pad including a window can also be formed using additive manufacturing. For example, the polishing layer from the reaction mixture can be formed around a window material that is placed on the build platform. As another example, the polishing layer can be formed with an opening in that a window is later placed. As yet another alternative, the window itself can be formed by additive manufacture. For example, the window could first be formed by additive manufacture in the vessel 1 of the apparatus and then the polishing layer formed by additive manufacture around the window. As another example the polishing layer can be formed with a gap for the window by additive manufacture as disclosed herein and then the window can be formed by additive manufacture in the gap. The window material can be, for example, polyurethanes, acrylic polymers, cyclic olefin co-polymers (e.g., TOPAS 8007, etc.). Use of polyurethane materials can be helpful in pads where the polishing layer, subpad layer, or both are also polyurethanes. A specific set of examples of aliphatic polyurethanes for windows can be found, for example, in U.S. Pat. No. 10,293,456.

### EXAMPLES

A reaction mixture was prepared including Component 1—small molecule (A) that was 1,2-diallyl phthalate (DAP) or diallyl isophthalate (DAIP); Component 2—an oligomeric molecule. A2a is derived from either PTMEG-based pre-polymer terminated with TDI and then reacted with allyl phenol. A2b is a low molecular weight diol based prepolymer terminated with MDI and then reacted with allyl phenol. A2c is a low molecular weight diol based prepolymer terminated with MDI and then reacted with eugenol; Component 3—a molecule (B) compound having more than 2 thiol functional groups to provide crosslinking where TMPMP is Trimethylolpropane tris(3-mercaptopropionate) and PTMP is Pentaerythritol tetrakis (3-mercaptopropionate); Component 4—molecule (B) dithiol functional compound to provide chain extension where GDMP is ethylene glycol bis(3-mercaptopropionate) and HDT is 1,6-hexanedithiol; and diphenyl(2,4,6-trimethylbenzoyl)phosphine oxide (TPO) as a photoinitiator at 1 weight percent based on total weight of the reaction mixture. The amounts and identities of components 1-4 are shown in Table 1. Weight percents are based on total weight of the reaction mixture. All examples were prepared with a mole ratio of 1:1 for the ethylenically unsaturated to the thiol groups.

TABLE 1

| | Component 1 | Component 2 | Component 3 - crosslinker | Component 4 |
|---|---|---|---|---|
| Ex. | (Wt %) | (Wt %) | (Wt %) | (Wt %) |
| 1 | DAP | A2a | TMPMP | GDMP |
| | (31%) | (31%) | (10%) | (28%) |
| 2 | DAP | A2b | TMPMP | GDMP |
| | (18%) | (44%) | (20%) | (18%) |
| 3 | DAP | A2c | TMPMP | GDMP |
| | (20%) | (42%) | (29%) | (9%) |
| 4 | DAIP | A2c | PTMP | GDMP |
| | (26%) | (35%) | (23%) | (15%) |
| 5 | DAIP | A2c | PTMP | GDMP |
| | (26%) | (35%) | (28%) | (10%) |
| 6 | DAIP | A2c | PTMP | HDT |
| | (27%) | (38%) | (24%) | (10%) |
| 7 | DAIP | Diallyl Bisphenol A | PTMP | GDMP |
| | (3%) | (52%) | (33%) | (11%) |

Examples 1-7 and a photocurable acrylate composition were film casted and photocured under a mercury lamp at 50 mW/cm² for 5 min on each side. All samples were non-porous, and they did not contain any composite fillers, such as polymeric microspheres or polymeric particles. Glass transition temperature (Tg) according to ASTM D5279-21 and selecting the temperature at maximum tan delta. Tensile Modulus according to ASTM D412, Elongation according to ASTM D412-05,toughness according to ASTM D412. The photocured acrylate and Examples 1-3 were also tested for cut rate by the following method: Sample specimens for wear testing were rings with an outer diameter of ⅞″ (2.2 cm) and inner hole cutout diameter of ⅜″ (0.95 cm) providing ½″ (1.3 cm) rim width. Samples were either punched from pad/plaque samples or photocured in a PTFE mold of the same dimensions with the Dymax 2000-EC Photocuring Flood System described above. Samples were loaded on a Vue-More Manufacturing; VEXTA gear head for sample disc rotation small scale polisher (SSP) and conditioned against a 4.25 inch (10.8 cm) diameter Saesol AK45 disc (170 μm diamonds with a 315 μm spacing). The conditioning disk was rotated at 3 rpm (clockwise), and the sample was rotated 300 rpm (counterclockwise) under a downforce of 1.78 psi (12.3 kPa) measured as pressed against the rotating diamond conditioning disk. The samples pressed against the conditioning disk at the midpoint between the center and the perimeter of the conditioning disk. The tests were performed in room temperature DI water that was not changed or recirculated. Wear data were acquired by removing the sample at five to thirty minute time increments and measuring thickness and a Keyence CL-3000 confocal displacement sensor. Thickness measurements were taken at three points, each spaced 120° around the sample ring and averaged for each time point. These wear results are shown in Table 2.

TABLE 2

| | Mech Data & Wear | | | | |
|---|---|---|---|---|---|
| | | | | | Unfilled |
| | | Median | Median | | Cut |
| | Tg | Elongation, | Modulus | Toughness | Rate |
| Ex. # | (° C.) | % | (MPa) | (MPa) | (mmm/h) |
| Acrylate | 80 | 6 | 809 | 0.028 | 2.3 |
| (Comparative) | | | | | |
| 1 | −5 | 255 | 1.28 | 2.08 | 0.56 |
| 2 | 25 | 415 | 7.9 | 7.1 | 1.1 |
| 3 | 33 | 174 | 127 | 9.8 | 1.3 |
| 4 | 29 | 231 | 108 | 17.8 | — |
| 5 | 29 | 151 | 239 | 13.9 | — |
| 6 | 43 | 133 | 347 | 16.9 | — |
| 7 | 27 | 164 | 330 | 9.69 | — |

### Polishing Pad Preparation

Reaction mixtures of Examples 4-6 were each individually poured into a 12″ (30.5 cm) circular mold and cured with a mercury lamp at an incident intensity of 50 milliwatts per square centimeter (mW/cm²) for 5 min on each side. Samples were then milled to a thickness of 0.080″ (0.2 cm) and grooved with a circular groove pattern (0.03″ wide×0.08″ pitch-0.076×0.2 cm) using a computer numerical control (CNC) mill. The samples were then laminated onto a Suba IV subpad from DuPont and die-punched to a 9″ (22.9 cm) final diameter.

Comparative non-photocured cast polyurethane samples for polish evaluation were drawdown casted and cured at 104° C. for 16 h. The cured samples were then faced, grooved, laminated, and punched in the same manner as the photocured samples. The comparative polyurethane A is characterized by a modulus of 348 MPa and an elongation of 298%. Comparative polyurethane B is characterized by a modulus of 183 MPa and an elongation of 430%.

### Polishing Procedure:

Polishing tests were completed using a Bruker TriboLab benchtop CMP tool. A Saesol AF38 diamond conditioning disk was used to break-in (10 minutes) and condition (10 s, ex-situ) each pad under DI water before polishing. TEOS wafers were polished for 60 s each at downforces of 3, 5, and 7 psi (20.7, 34.5 and 48.3 kPa) and platen: head RPMs of 150:151, 225:226, and 300:301 (18 total runs per pad). For all polish tests, Klebosol 1730 slurry was used at a flow rate of 100 mL/min. Results are shown in Table 3.

TABLE 3

| | Platen/ | Polish | Polish Down | Average Center |
|---|---|---|---|---|
| | Head | Down | Force | TEOS RR |
| Pad Sample | Speed (rpm) | Force (psi) | (kPa) | (Å/min) |
| High Modulus Polyether PU | 150/151 | 3 | 20.7 | 2234 |
| (non-photocured) | | 5 | 34.5 | 3323 |
| | | 7 | 48.3 | 3960 |
| | 225/226 | 3 | 20.7 | 3468 |
| | | 5 | 34.5 | 4422 |
| | | 7 | 48.3 | 6193 |
| | 300/301 | 3 | 20.7 | 3600 |
| | | 5 | 34.5 | 6428 |
| | | 7 | 48.3 | 8364 |
| Low Modulus Polyether PU | 150/151 | 3 | 20.7 | 1710 |
| (non-photocured) | | 5 | 34.5 | 2361 |
| | | 7 | 48.3 | 3242 |
| | 225/226 | 3 | 20.7 | 1965 |
| | | 5 | 34.5 | 4583 |
| | | 7 | 48.3 | 5065 |
| | 300/301 | 3 | 20.7 | 2396 |
| | | 5 | 34.5 | 4180 |
| | | 7 | 48.3 | 5403 |
| Example 4 | 150/151 | 3 | 20.7 | 1627 |
| | | 5 | 34.5 | 3166 |
| | | 7 | 48.3 | 4105 |
| | 225/226 | 3 | 20.7 | 2371 |
| | | 5 | 34.5 | 4381 |
| | | 7 | 48.3 | 6594 |
| | 300/301 | 3 | 20.7 | 3179 |
| | | 5 | 34.5 | 5764 |
| | | 7 | 48.3 | 7861 |
| Example 5 | 150/151 | 3 | 20.7 | 1271 |
| | | 5 | 34.5 | 2769 |
| | | 7 | 48.3 | 4321 |
| | 225/226 | 3 | 20.7 | 1979 |
| | | 5 | 34.5 | 3363 |
| | | 7 | 48.3 | 5183 |
| | 300/301 | 3 | 20.7 | 2354 |
| | | 5 | 34.5 | 4661 |
| | | 7 | 48.3 | 6521 |
| Example 6 | 150/151 | 3 | 20.7 | 1478 |
| | | 5 | 34.5 | 2693 |
| | | 7 | 48.3 | 4415 |
| | 225/226 | 3 | 20.7 | 2010 |
| | | 5 | 34.5 | 3731 |
| | | 7 | 48.3 | 5673 |
| | 300/301 | 3 | 20.7 | 2164 |
| | | 5 | 34.5 | 4689 |
| | | 7 | 48.3 | 6747 |

This disclosure further encompasses the following aspects.

Aspect 1: A chemical mechanical polishing pad comprising photocured polymer wherein the photocured polymer is the photoinitiated reaction product of a photocurable material that is free of molecules comprising (meth)acrylate groups and the photocurable material comprises molecules having two or more functional groups wherein the functional groups include a thiol group and ethylenically unsaturated group other than a (meth)acrylate group and the photocure includes reaction of the thiol group with the ethylenically unsaturated group, provided at least some of the molecules comprise three or more functional groups.

Aspect 2: The chemical mechanical polishing pad of Aspect 1 wherein the molecules having two or more functional groups comprise first molecules having two or more ethylenically unsaturated groups and second molecules having two or more thiol groups, provided at least a portion of the first molecules comprise at least three or more ethylenically unsaturated groups or at least a portion of the second molecules comprise three or more thiol groups.

Aspect 3. The chemical mechanical polishing pad of Aspect 1 wherein the molecules having two or more functional groups include a heterotelechelic molecule having an ethylenically unsaturated group and a thiol group.

Aspect 4. The chemical mechanical polishing pad of any of the previous Aspects wherein the reaction mixture comprises a photoinitiator that generates a radical upon exposure to activating wavelengths of radiation.

Aspect 5. The chemical mechanical polishing pad of any of the previous Aspects wherein the ethylenically unsaturated groups include allyl groups.

Aspect 6. The chemical mechanical polishing pad of Aspect 5 wherein the reaction mixture comprises a photoinitiator that generates a base upon exposure to activating wavelengths of radiation.

Aspect 7. The chemical mechanical polishing pad of Aspect 2 wherein the first molecule comprises the reaction product of a polyisocyanate comprising an oligomer, a multifunctional isocyanate monomer, or a mixture thereof and an ethylenically unsaturated end-capping agent.

Aspect 8. The chemical mechanical polishing pad of Aspect 2 wherein the first molecule comprises an oligomer comprising two or more ethylenically unsaturated groups and a monomer comprising two or more ethylenically unsaturated groups and the second molecule comprises one or more of alkyl multifunctional thiols, aromatic multifunctional thiols, multifunctional mercaptopropionate esters, multifunctional thioglycolate esters, multifunctional mercaptoacetate esters, thiol-terminated oligomers having two or more thiol groups.

Aspect 9. The chemical mechanical polishing pad of any of the previous Aspects comprising less than 0.05 weight percent of abrasive particles based on total weight of the polishing pad.

Aspect 10. A polishing pad of any of the previous Aspects formed from a method comprising providing the photocurable material in a vessel, selectively curing by irradiation a portion the photocurable material to form a cured structure, selectively curing by irradiating an additional portion of the photocurable material to further build the cured structure, repeating the selective curing by irradiation until the cured structure has the form of the polishing layer of the polishing pad.

Aspect 11. The polishing pad of Aspect 10 wherein the photocurable material provided includes the following:
i) monomers or oligomers or mixtures thereof having two or more ethylenically unsaturated groups and
ii) monomers or oligomers or mixtures thereof having two or more thiol groups.

All ranges disclosed herein are inclusive of the endpoints, and the endpoints are independently combinable with each other (e.g., ranges of “up to 25 wt. %, or, more specifically, 5 wt. % to 20 wt. %”, is inclusive of the endpoints and all intermediate values of the ranges of “5 wt. % to 25 wt. %,” etc.). Moreover, stated upper and lower limits can be combined to form ranges (e.g. “at least 1 or at least 2 weight percent” and “up to 10 or 5 weight percent” can be combined as the ranges “1 to 10 weight percent”, or “1 to 5 weight percent” or “2 to 10 weight percent” or “2 to 5 weight percent”).

The disclosure may alternately comprise, consist of, or consist essentially of, any appropriate components herein disclosed. The disclosure may additionally, or alternatively, be formulated so as to be devoid, or substantially free, of any components, materials, ingredients, adjuvants or species used in the prior art compositions or that are otherwise not necessary to the achievement of the function or objectives of the present disclosure.

All cited patents, patent applications, and other references are incorporated herein by reference in their entirety. However, if a term in the present application contradicts or conflicts with a term in the incorporated reference, the term from the present application takes precedence over the conflicting term from the incorporated reference.

Unless specified to the contrary herein, all test standards are the most recent standard in effect as of the filing date of this application, or, if priority is claimed, the filing date of the earliest priority application in which the test standard appears.

What is claimed is:

1. A chemical mechanical polishing pad comprising a photocured polymer wherein the photocured polymer is the photoinitiated reaction product of a photocurable material that is free of molecules comprising (meth)acrylate groups and the photocurable material comprises molecules having two or more functional groups wherein the functional groups include a thiol group and ethylenically unsaturated group other than a (meth)acrylate group and the photocure includes reaction of the thiol group with the ethylenically unsaturated group, provided at least some of the molecules comprise three or more functional groups.

2. The chemical mechanical polishing pad of claim 1 wherein the molecules having two or more functional groups comprise first molecules having two or more ethylenically unsaturated groups and second molecules having two or more thiol groups, provided at least a portion of the first molecules comprise at least three or more ethylenically unsaturated groups or at least a portion of the second molecules comprise three or more thiol groups.

3. The chemical mechanical polishing pad of claim 1 wherein the molecules having two or more functional groups include a heterotelechelic molecule having an ethylenically unsaturated group and a thiol group.

4. The chemical mechanical polishing pad of claim 1 wherein the reaction mixture comprises a photoinitiator that generates a radical upon exposure to activating wavelengths of radiation.

5. The chemical mechanical polishing pad of claim 4 wherein the ethylenically unsaturated groups include allyl groups.

6. The chemical mechanical polishing pad of claim 1 wherein the reaction mixture comprises a photoinitiator that generates a base upon exposure to activating wavelengths of radiation.

7. The chemical mechanical polishing pad of claim 2 wherein the first molecule comprises the reaction product of a polyisocyanate comprising an oligomer, a multifunctional isocyanate monomer, or a mixture thereof and an ethylenically unsaturated end-capping agent.

8. The chemical mechanical polishing pad of claim 2 wherein the first molecule comprises an oligomer comprising two or more ethylenically unsaturated groups and a monomer comprising two or more ethylenically unsaturated groups and the second molecule comprises one or more of alkyl multifunctional thiols, aromatic multifunctional thiols, multifunctional mercaptopropionate esters, multifunctional thioglycolate esters, multifunctional mercaptoacetate esters, thiol-terminated oligomers having two or more thiol groups.

9. The polishing pad of claim 1 formed from a method comprising providing the photocurable material in a vessel, selectively curing by irradiation a portion the photocurable material to form a cured structure, selectively curing by irradiating an additional portion of the photocurable material to further build the cured structure, repeating the selective curing by irradiation until the cured structure has the form of the polishing layer of the polishing pad.

10. The polishing pad of claim 9 wherein the photocurable material provided includes the following:
i) monomers or oligomers or mixtures thereof having two or more ethylenically unsaturated groups and
ii) monomers or oligomers or mixtures thereof having two or more thiol groups.
